(19) United States
(12) Patent Application Publication
(10) Pub. No.: US 2025/0290978 A1
(43) Pub. Date: Sep. 18, 2025

(54) CONTROLLER AREA NETWORK (CAN) BUS DIAGNOSTICS

(71) Applicant: Raven Industries, Inc., Sioux Falls, SD (US)

(72) Inventors: Justin Krosschell, Sioux Falls, SD (US); Robert Charles Haar, Volga, SD (US); Jeff VanRoekel, Sioux Falls, SD (US); Russell James Cumber, Garretson, SD (US)

(21) Appl. No.: 19/076,182

(22) Filed: Mar. 11, 2025

Related U.S. Application Data
(60) Provisional application No. 63/566,651, filed on Mar. 18, 2024.

(51) Int. Cl. G01R 31/317

(52) U.S. Cl. CPC G01R 31/31703; G01R 31/31713; G01R 31/31725

(57) ABSTRACT

Systems and techniques may generally be used for performing a diagnostic test on a Controller Area Network (CAN) bus. An example system may include a transceiver including a buffer to store a voltage difference measured by a differential amplifier from a CAN bus and output the voltage difference. The example system may include a controller including an analog to digital converter (ADC) to convert the voltage difference to a digital signal, and processing circuitry to determine a relative margin between a maximum voltage of a detection window and the voltage difference using the digital signal.

### CLAIM OF PRIORITY

This application claims the benefit of priority to U.S. Provisional Application No. 63/566,651 filed Mar. 18, 2024, titled “CONTROLLER AREA NETWORK (CAN) BUS DIAGNOSTICS,” which is hereby incorporated herein by reference in its entirety.

### BACKGROUND OF THE INVENTION

A Controller Area Network (CAN) bus is a bus used on vehicles to allow nodes on the bus to communication with each other. The CAN bus may follow a standard (e.g., a standard set by the International Organization for Standardization (ISO)) or may be customized for a particular use (e.g., agricultural vehicles). The CAN bus may include one or more nodes, with each node including a transceiver and processing circuitry (e.g., a microprocessor, a system on a chip, a central processing unit, a graphics processing unit, software, etc.). The transceiver may be used to output or receive a signal on a line of the CAN bus, which typical includes two lines.

### SUMMARY OF THE INVENTION

The present systems and techniques may be used for diagnosing one or more issues on a CAN bus. For example, a controller may include an analog to digital converter (ADC) to receive a voltage difference received from a buffer of a transceiver, the voltage difference measured by a differential amplifier from a Controller Area Network (CAN) bus. The controller may include processing circuitry to determine a relative margin between the voltage difference and a maximum voltage of a detection window.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates a block diagram of a node of a CAN bus in accordance with some examples.

FIG. 2 illustrates a block diagram of processing circuitry for use with a CAN bus in accordance with some examples.

FIG. 3 illustrates a scope graph including a voltage difference in accordance with some examples.

FIG. 4 illustrates an eye diagram including a detection window of a receiver in accordance with some examples.

FIG. 5 illustrates a scope graph including a degraded signal in accordance with some examples.

FIG. 6 illustrates a flowchart showing a technique for determining a relative margin at a node of a CAN bus in accordance with some examples.

FIG. 7 illustrates generally an example of a block diagram of a machine upon which any one or more of the techniques discussed herein may perform in accordance with some examples.

### DETAILED DESCRIPTION OF THE DRAWINGS

The systems and techniques described herein provide information regarding signaling on a CAN bus. Certain CAN bus routing common practices and common CAN bus configurations on agricultural machines affect the ability to clearly communicate in certain circumstances. Troubleshooting may be frustrating or complicated for a typical user or service personnel. A common customer for a CAN transceiver may be an automotive customer that works on a closed or defined network. However, agricultural vehicles do not typically have closed or defined networks, so typical solutions may not work.

Some issues in using CAN buses on agricultural machines arise due to the uniqueness of the machines. For example, CAN bus routing practices on agricultural machines may be run through multiple connectors or bulkhead, may push or exceed node count limits, or push or exceed bitrate of CAN bus length in view of length limits (e.g., to obtain more data from a device at a machine endpoint). Typically, differential CAN bus topology requires terminators to be placed at ends of the bus to limit reflections of signals. Other issues that may occur on agricultural machines include damage or lost terminators, due to more open design of the machines or harsher conditions, changing CAN bus topology over machine lifetime, industry standard methods to change configuration outside of the factory (e.g., connecting implements), aftermarket equipment or implements that are added or removed in sub-optimal ways affecting cable or routing topology, or the like.

Specific agricultural implementations of a CAN bus may conform to a standard, such as ISO 11783, which is a communication protocol for tractors and other agricultural machinery. A bus that conforms to ISO 11783 or another standard may include a long cable run from large implements to user displays or interfaces in a cab, provide interoperability advantages between manufacturers or implements but with an undefined or complex network topology that may not be tested in its actual layout, malfunction when adding a new piece of equipment, or allow for frequent connect and disconnect of cabling between implements that causes the cabling or implements to wear out over time or need maintenance or diagnosis. The systems and techniques described herein provide solutions to the above and other technical problems.

A CAN transceiver resides between a physical two wire differential bus layer and processing circuitry (e.g., a microcontroller or microprocessor) that interprets the bus state through a combination of hardware and software, for example. When the transceiver detects a transaction on the bus, the transceiver converts the signal into a low-voltage serial format for processing by a microcontroller or a microprocessor. The transceiver may convert between the CAN bus wire differential voltage to a single voltage or vice versa. The microcontroller or microprocessor digitally interprets a transaction and timing based on the output of the transceiver. When processing circuitry transmits via the transceiver onto the CAN bus wires, is received back at the processing circuitry because the transaction is received on the bus after traversing the bus.

The timing conditions presented on the serial bus may be interpreted by the hardware and software on the processing circuitry. For example, when the processing circuitry identifies a valid transaction, the processing circuitry may communicate via standard bus protocols. A CAN transceiver may auto adjust a margin detection.

In an example, a bus health check may be run on certain intervals (or on demand from user via a user as a start of season health check). During the health test, one or more nodes may operate at higher baud rates and the results may be evaluated. The behavior and signature of the bus dynamics may be captured during a series of tests. For example, a start may include lower than 250 kbaud, which may be incremented up to above 1 Mbaud. In an example, a bus health check may be run at certain intervals or on demand from a user (e.g., via a user as a start of season health check). During the bus health check, one or more nodes may operate at higher baud rates. The behavior and signature of the bus dynamics may be evaluated during the bus health check, for example including evaluating a pattern over a series of tests. For example, the baud rate may start at lower than 250 kbaud and be increased up to at least 1 Mbaud.

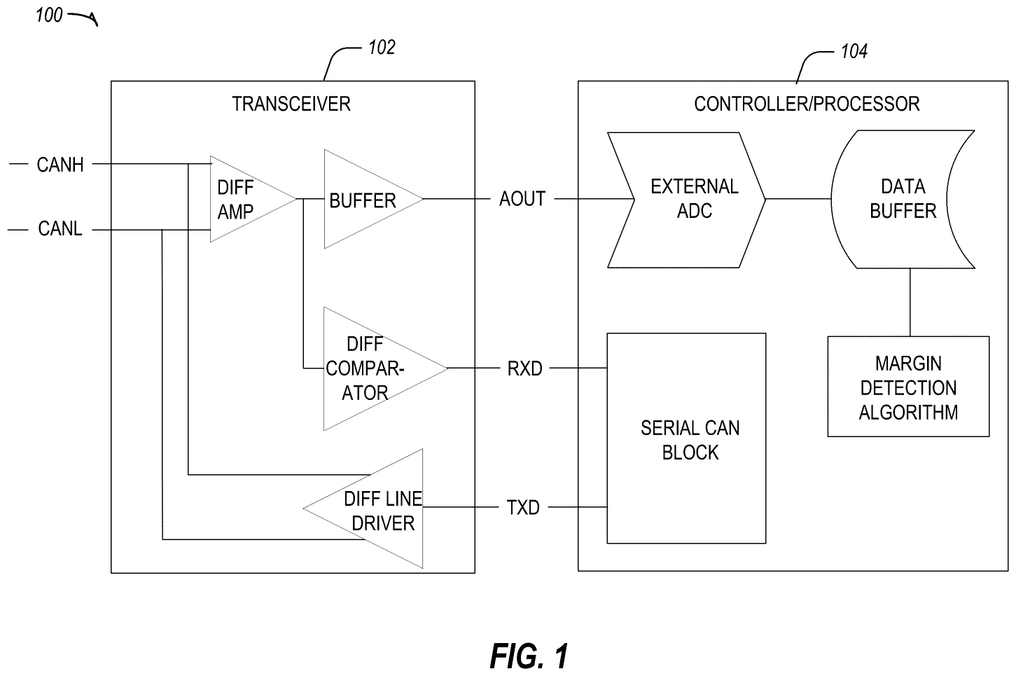

FIG. 1 illustrates a block diagram of a node 100 of a CAN bus in accordance with some examples. The node 100 includes a transceiver 102 and a controller 104 (e.g., a processor, processing circuitry, etc.). The node 100 may include an Electronic Control Unit (ECU). The transceiver 102 includes a differential amplifier to receive a voltage on a CAN high voltage line and a CAN low voltage line. The differential amplifier may apply a gain to a difference in voltage between the voltage received on the CAN high voltage line and the voltage received on the CAN low voltage line, resulting in an output voltage. The output voltage may be output to a differential comparator and a buffer, in some examples. The differential comparator may output data to be received at a serial CAN block of the controller 104, which may transmit data to a differential line driver of the transceiver 102. The differential line driver may be connected to the CAN high voltage line or the CAN low voltage line.

In an example, a buffer is added to the transceiver 102. An analog output pin may be used with the buffer in the transceiver 102 to send the output voltage to an ADC of the controller 104. The buffer on the transceiver 102 may collect samples over time. The controller 104 may include a buffer to store data. The controller 104 may include processing circuitry to perform a margin detection algorithm (e.g., by retrieving data stored in the data buffer of the transceiver 102 received from the ADC). The algorithm may identify a margin detection window, which may be tracked over time. A threshold may be used such as to indicate that there is a new problem on the CAN line, etc.

Construction machinery or agricultural machinery may be more likely to be open or customized versus traditional car systems, which are more closed, unmodified, or unmodifiable. A customized CAN bus may include a modification from a dealer, a farmer, a customer, etc. This may include a modification of the vehicle with after-market goods. Any modification to the CAN bus may modify a CAN network of the CAN bus. For example, a length of the CAN network may be longer than a typical CAN network or past a specified length, which may cause degradation in a signal on a CAN line. A modification to a portion of the CAN network may cause data degradation, signal interference, or the like.

A CAN terminator absorbs reflections, but an issue may arise when a node is added such that the terminator is no longer at an end of the bus. Ends of the CAN bus in some systems are more likely to be damaged, which may cause signaling issues. Adding a node changes the bus topology and may cause some other node to stop functioning or have a degraded signal (or the added node may stop functioning or have a degraded signal).

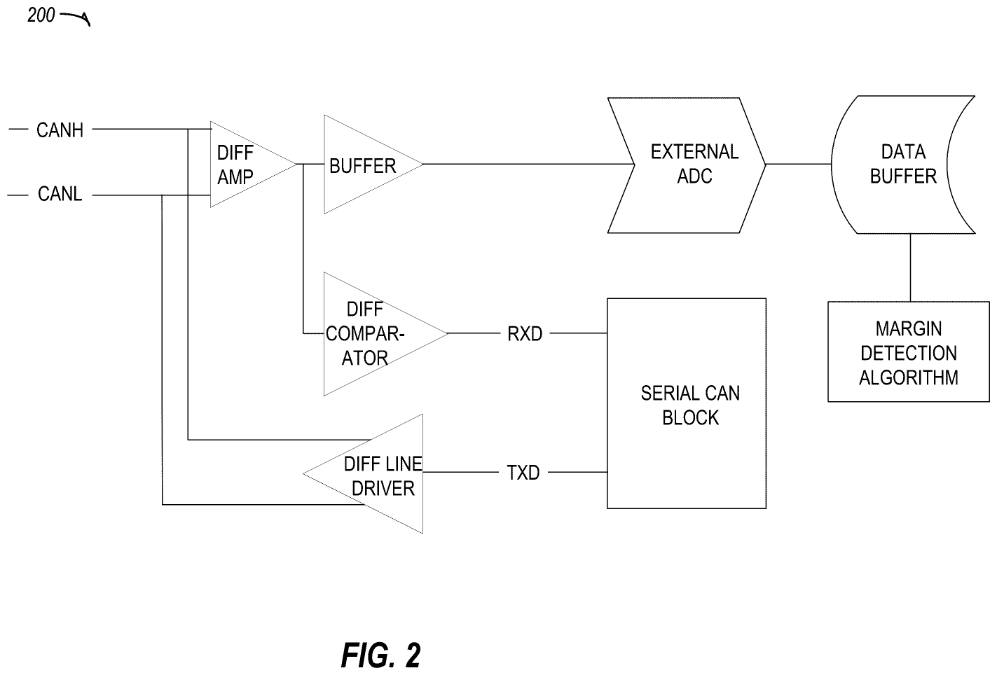

FIG. 2 illustrates a block diagram of processing circuitry 200 for use with a CAN bus in accordance with some examples. The processing circuitry 200 may be on a node of a CAN bus, on a transceiver (e.g., of a node on a CAN bus), on a controller (e.g., of a node on a CAN bus), as stand-alone circuitry (e.g., a system on a chip), or the like. The processing circuitry 200 may be implemented using entirely hardware, entirely software, or a combination of hardware and software. The components of the processing circuitry 200 shown in FIG. 2 may be used similarly to or the same as the components described above with respect to FIG. 1. The difference between FIG. 1 and FIG. 2 is that in FIG. 2 all components are combined in processing circuitry, whereas in FIG. 1 some components are combined in the transceiver 102 and other components are combined in the controller 104.

The processing circuitry 200 includes a differential amplifier to receive a voltage on a CAN high voltage line and a CAN low voltage line. The differential amplifier may apply a gain to a difference in voltage between the voltage received on the CAN high voltage line and the voltage received on the CAN low voltage line, resulting in an output voltage. The output voltage may be output to a differential comparator and a first buffer, in some examples. The differential comparator may output data to be received at a serial CAN block, which may transmit data to a differential line driver. The differential line driver may be connected to the CAN high voltage line or the CAN low voltage line.

In an example, the first buffer is added to the processing circuitry 200. An analog output pin may be used with the first buffer to send the output voltage to an ADC. The first buffer may collect samples over time. The processing circuitry 200 may include a second buffer to store data. The processing circuitry 200 may be used to perform a margin detection algorithm (e.g., by retrieving data stored in the second buffer received from the ADC). The algorithm may identify a margin detection window, which may be tracked over time. A threshold may be used such as to indicate that there is a new problem on the CAN line, etc.

While many systems and techniques described herein have included using a voltage difference, other alternate physical aspects may be measured to determine CAN bus health. In some examples, two or more physical signals may be combined for an aggregate determination of CAN bus status (e.g., two voltages). In some examples, a physical signal may be captured by an oscilloscope (e.g., a waveform indicative of bad bus health), an Edge Rate analysis may be performed (e.g., a rate of changes in voltage levels), an impedance measurement may be captured, a difference pulse width (e.g., for a standard frame bit) may be identified, or the like, instead of or in addition to a voltage difference. In an example, a frequency of occurrence of runt pulses or fat pulses on a bus may be used to determine whether a timing quality issue has occurred on a device on the bus.

In some examples, data related to operation of a machine that the CAN bus is on may be used to evaluate health of the CAN bus or other attributes of health of the machine. For example, machine data may include machine propulsion conditions, machine steering conditions, status or operation conditions, total busload changes, current environmental conditions, or the like. For example, machine propulsion conditions may be recorded or used to diagnose a CAN bus error, such as identifying that a CAN error or bus margin degradation occurs only when the machine is going faster than x miles per hour or only when the machine is in 5th gear. Machine steering conditions may similarly be used to diagnose a CAN error or bus margin degradation, such as when an error or degradation only occurs when the machine is turning right or above y yaw rate. Other operational parameters such as implement status or operation conditions may be used, such as an error that occurs when the machine is performing tillage operations when the tines or disks are engaged with the ground, but where no errors occur while the tillage implement is attached but not engaged. A total busload change may correspond to an error or degradation when a perception controller or a perception controller with a specific software version or hardware version is on the bus. For example, a specific software version on an ECU may increase bus load or utilization (e.g., by reducing bus capacity for transmitting frames) by some percentage under all conditions or under some specific operating condition. Current environmental conditions may be used to identify an error. For example, a CAN error or bus margin degradation that occurs when humidity is high (e.g., a rainy day) or temperature is low (e.g., in winter) may be identified. A temperature, humidity, or vibration sensor on a machine may be used to correlate faults to present operating conditions. From a proactive service standpoint “freeze framing” machine conditions during error states is helpful to recreate an intermittent fault as opposed to a static fault. A technician may resolve an issue if they know how to create the conditions.

In some examples, the systems and techniques described herein may be used for monitoring bus health at multiple nodes at different spots on the bus, for example to help pinpoint cabling issues or an open wire.

Data may be collected from one or more machines or nodes, and analysis or aggregating of the data may be centralized (e.g., at a cloud server, for example with machine learning), or distributed (e.g., local server running in at a machine, dealer, region, etc.).

A server as described herein may include a computing device on a vehicle, one or more devices in a cloud system, for example remote from a vehicle, a computing device (e.g., a mobile device, a computer, etc.), or the like.

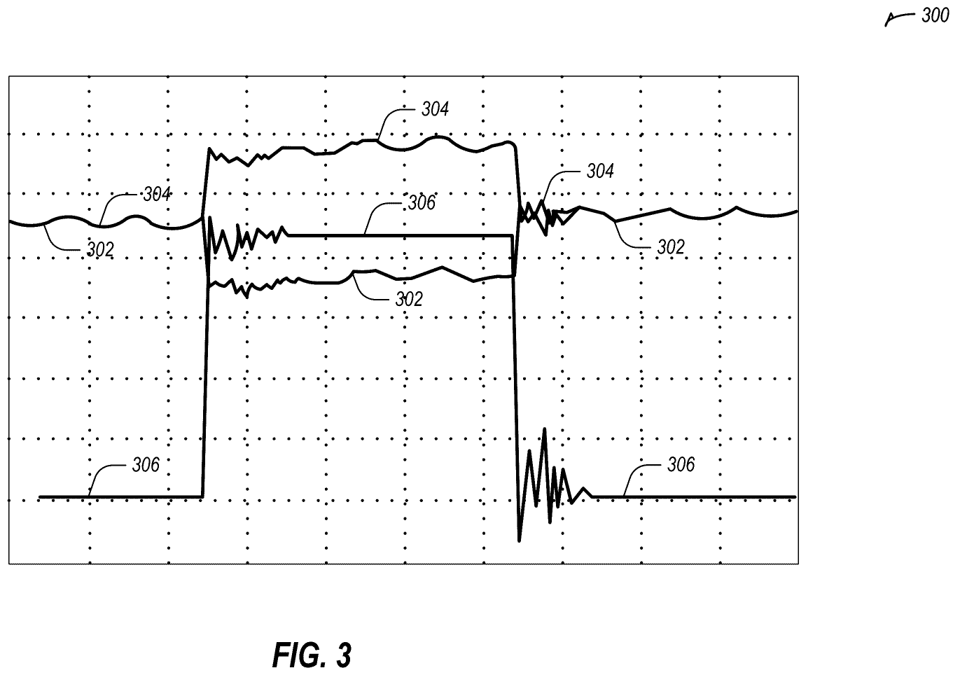

FIG. 3 illustrates a scope graph 300 including a voltage difference in accordance with some examples. The scope graph 300 includes a first signal 302 and a second signal 304 (the signals overlap substantially initially and at the end of the signal). These signals 302 and 304 represent a voltage received on a first line and a second line, respectively, of a CAN bus. The third signal 306 shown in the scope graph 300 is a difference signal between the first signal 302 and the second signal 304 (e.g., additively combining the signals).

The systems and techniques described herein may be used for measuring physical bus performance and margins while limiting cost of implementation. For example, these may include exposing the differential input amplifier that exists in the CAN transceiver to a device that can interpret the physical signal (like a low voltage ADC internal to a micro and a processing algorithm that interprets the differential bus signal). This technique allows us to measure receive margin on single bits of a transaction.

The third signal 306 in FIG. 3 represents an output of a differential amplifier in a CAN transceiver. In some examples there may be some jitter or reflections in the signal (e.g., at the transitions of the devices on the bus). In some examples, the output is buffered at the logic levels of the transmit data (TXD)/receive data (RXD) interface, which may be interpreted with an external ADC.

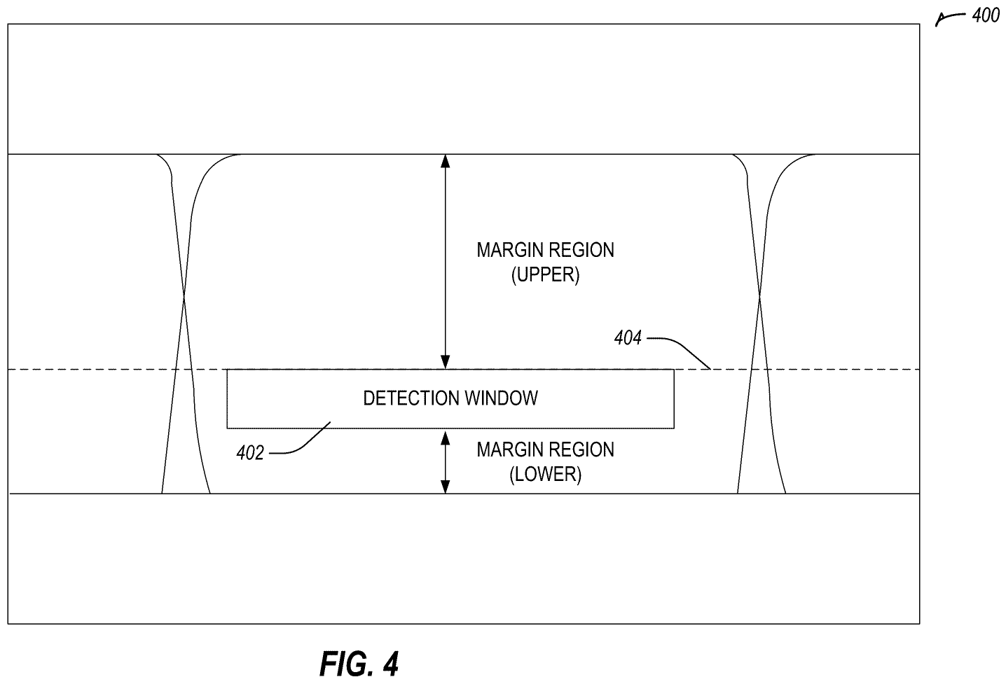

FIG. 4 illustrates an eye diagram 400 including a detection window 402 of a receiver in accordance with some examples. The detection window 402 includes an upper limit 404. The upper limit 404 may be compared to signal of the eye diagram 400 to determine a margin region (upper). A lower margin region may be present below the detection window 402, such as for avoiding noise. The detection window 402 may include a duration throughout the eye diagram 400 (e.g., shown as a width in FIG. 4). The detection window 402 may include a voltage range (e.g., 500 to 1000 mV, for example) measurement throughout the eye diagram 400 (e.g., shown as a height in FIG. 4).

The voltage signal may be put into an ADC to determine a relative margin on the receiver detection window as shown in FIG. 4. As that measurement changes over time, a threshold may be set for alarming before the margins for valid communication are violated.

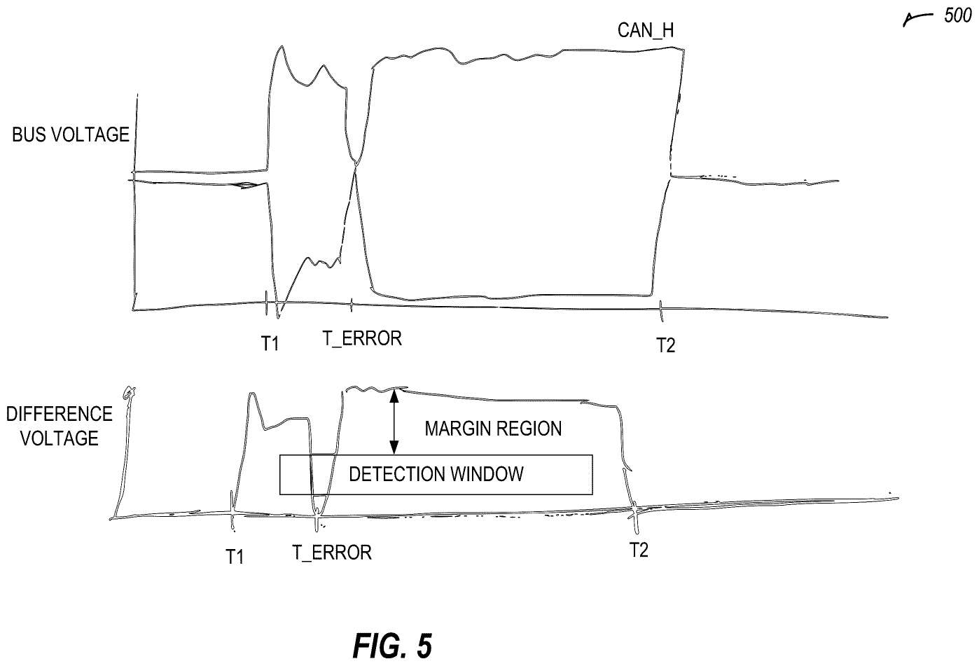

FIG. 5 illustrates a scope graph 500 including a degraded signal (shown as two line graphs) in accordance with some examples. A detection window is shown for reference, along with a degraded margin region. The margin region shown in the scope graph 500 is high for most of the detection window, but drops to zero (or becomes negative, infringing on the detection window) at the “T_error” point. This is a degraded signal that has no margin region and may lead to issues with detecting a signal in the detection window.

In some examples, a default margin level (e.g., a threshold, a minimum percentage of distance, etc.) may be used. In some examples, an alert may be issued when changes in margin are identified when compared with a baseline margin. In some examples, a forthcoming error on a margin detection window may be identified (e.g., based on a time-series of voltage differences indicating a trend).

Above the receiver detection window in FIGS. 4-5, as the signal degrades, 30% margin from the top of the window to the errors in the signal occurs, whereas in an initial state, optimal, or minimum threshold may be 90%. In some examples, the signal may be compared across a fleet, such as when there are several owned by a customer. For example, a fleet may include six vehicles, where one is at 50%, but the rest are at 80%. In this example, an indication may be output to check the configuration or connections on the 50% vehicle. A customer may opt into an agreement to share the data, and may receive an alert that there is a discrepancy (e.g., by collecting many customer's data when they opt in). Data and machine configuration may be stored based on an initial state, then later when a customer has an issue, their current state may be compared to the stored initial state.

In some examples, the voltage difference may be sampled and sent to a server. Comparison or alerting may be done by a server. For example, a diagnostic mode on the CAN bus may be activated, such as to reserve some amount of bus transmission cycle or sideband (e.g., cellular) for offboarding data and sending the data to the server for analysis.

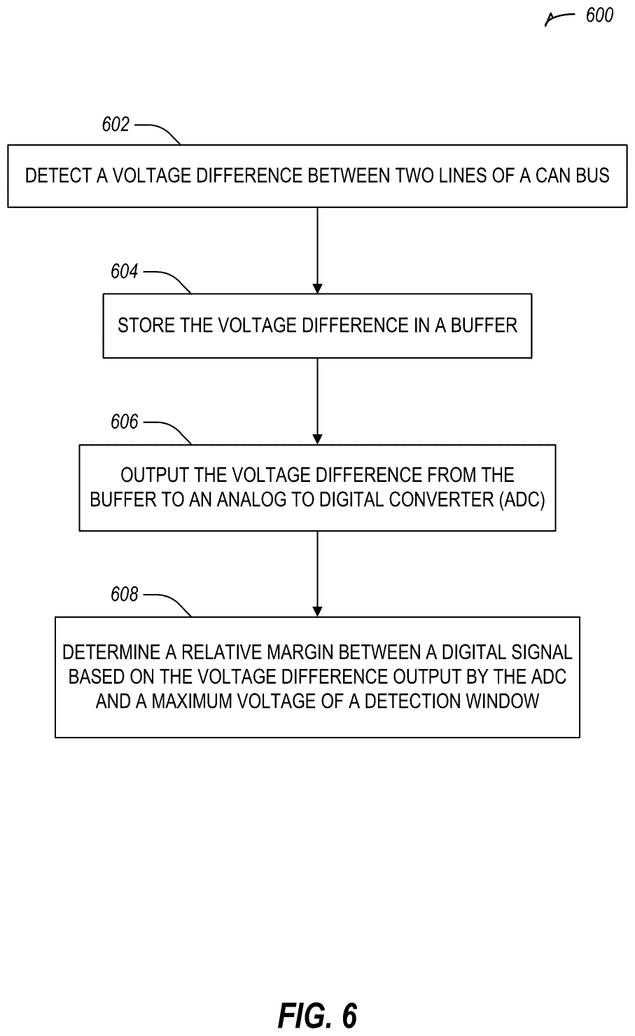

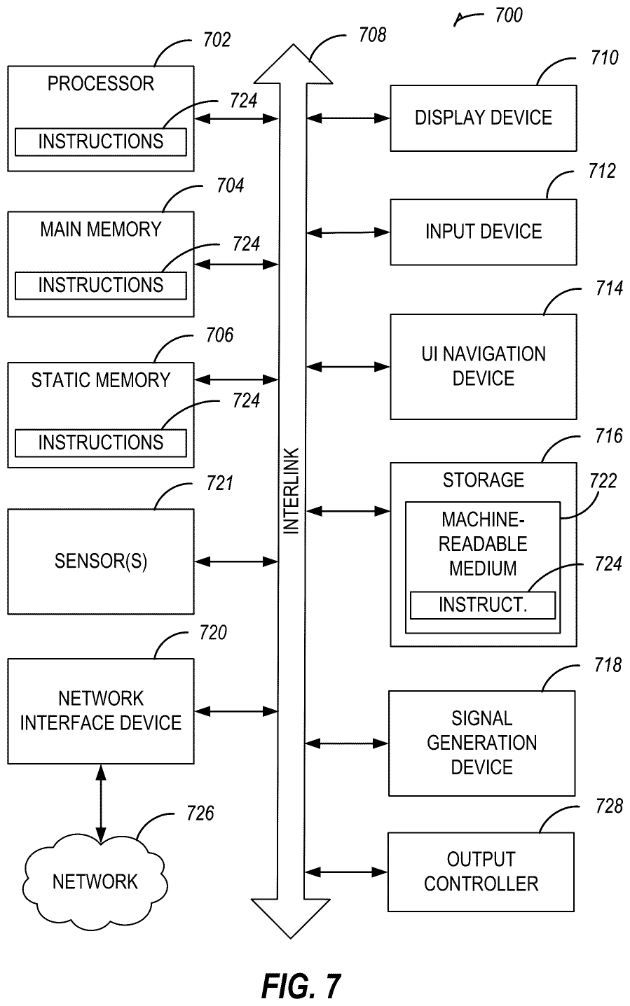

FIG. 6 illustrates a flowchart showing a technique 600 for determining a relative margin at a node of a CAN bus in accordance with some examples. In an example, operations of the technique 600 may be performed by processing circuitry, for example by executing instructions stored in memory. The processing circuitry may include a processor, a system on a chip, or other circuitry (e.g., wiring). For example, technique 600 may be performed by processing circuitry of a device (or one or more hardware or software components thereof), such as those illustrated and described with reference to FIG. 1 or 7.

The technique 600 includes an operation 602 to detect a voltage difference between two lines of a CAN bus. The CAN bus may be on an agricultural vehicle. In some examples, the CAN bus has a line length greater than a maximum standard line length (e.g., according to a CAN standard, such as CAN standard ISO 11898). In some examples, the CAN bus includes more nodes than a maximum standard number of nodes (e.g., according to a CAN standard, such as CAN standard ISO 11898).

The technique 600 includes an operation 604 to store the voltage difference in a buffer. The voltage difference may be identified from a signal sent by a transceiver or from a signal sent by another system on the CAN bus. The technique 600 includes an operation 606 to output the voltage difference from the buffer to an analog to digital converter (ADC).

The technique 600 includes an operation 608 to determine a relative margin between a digital signal based on the voltage difference output by the ADC and a maximum voltage of a detection window. In an example, the detection window is a preselected window having a minimum voltage, a maximum voltage, and a duration.

In an example, the technique includes an operation to use a data buffer to store a plurality of voltage differences, including the voltage difference, as a plurality of digital signals. In this example, determining the relative margin may include determining relative margins over time. In this example, the technique may include outputting an indication of degradation of relative margins of the plurality of voltage differences over time.

The technique may include amplifying, using a differential amplifier, a first voltage from a first line of the CAN bus and a second voltage from a second line of the CAN bus, and outputting the voltage difference based on the amplified first and second voltage. The technique may include outputting an indication that an addition of a new node caused the relative margin to violate a threshold. The technique may include comparing the relative margin to a diagnostic initial state measurement stored from a factory setting to determine whether the relative margin has degraded.

In an example, the technique includes an operation to compare the relative margin to a threshold. In this example, the technique may include outputting an alarm when the relative margin is below the threshold. In this example, the threshold may be a default threshold In this example, the threshold may be a custom threshold that is specified for a particular fleet (e.g., having a common owner or operator) or vehicle type (e.g., tractors, a particular type of tractor, etc.).

FIG. 7 illustrates generally an example of a block diagram of a machine 700 upon which any one or more of the techniques (e.g., methodologies) discussed herein may perform in accordance with some examples. In alternative embodiments, the machine 700 may operate as a standalone device or may be connected (e.g., networked) to other machines. In a networked deployment, the machine 700 may operate in the capacity of a server machine, a client machine, or both in server-client network environments. In an example, the machine 700 may act as a peer machine in peer-to-peer (P2P) (or other distributed) network environment. The machine 700 may be a personal computer (PC), a tablet PC, a set-top box (STB), a personal digital assistant (PDA), a mobile telephone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, may include, or may operate on, logic or a number of components, modules, or mechanisms. Modules are tangible entities (e.g., hardware) capable of performing specified operations when operating. A module includes hardware. In an example, the hardware may be specifically configured to carry out a specific operation (e.g., hardwired). In an example, the hardware may include configurable execution units (e.g., transistors, circuits, etc.) and a computer readable medium containing instructions, where the instructions configure the execution units to carry out a specific operation when in operation. The configuring may occur under the direction of the executions units or a loading mechanism. Accordingly, the execution units are communicatively coupled to the computer readable medium when the device is operating. In this example, the execution units may be a member of more than one module. For example, under operation, the execution units may be configured by a first set of instructions to implement a first module at one point in time and reconfigured by a second set of instructions to implement a second module.

Machine (e.g., computer system) 700 may include a hardware processor 702 (e.g., a central processing unit (CPU), a graphics processing unit (GPU), a hardware processor core, or any combination thereof), a main memory 704 and a static memory 706, some or all of which may communicate with each other via an interlink (e.g., bus) 708. The machine 700 may further include a display unit 710, an alphanumeric input device 712 (e.g., a keyboard), and a user interface (UI) navigation device 714 (e.g., a mouse). In an example, the display unit 710, alphanumeric input device 712 and UI navigation device 714 may be a touch screen display. The machine 700 may additionally include a storage device (e.g., drive unit) 716, a signal generation device 718 (e.g., a speaker), a network interface device 720, and one or more sensors 721, such as a global positioning system (GPS) sensor, compass, accelerometer, or other sensor. The machine 700 may include an output controller 728, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The storage device 716 may include a machine readable medium 722 that is non-transitory on which is stored one or more sets of data structures or instructions 724 (e.g., software) embodying or utilized by any one or more of the techniques or functions described herein. The instructions 724 may also reside, completely or at least partially, within the main memory 704, within static memory 706, or within the hardware processor 702 during execution thereof by the machine 700. In an example, one or any combination of the hardware processor 702, the main memory 704, the static memory 706, or the storage device 716 may constitute machine readable media.

While the machine readable medium 722 is illustrated as a single medium, the term “machine readable medium” may include a single medium or multiple media (e.g., a centralized or distributed database, or associated caches and servers) configured to store the one or more instructions 724.

The term “machine readable medium” may include any medium that is capable of storing, encoding, or carrying instructions for execution by the machine 700 and that cause the machine 700 to perform any one or more of the techniques of the present disclosure, or that is capable of storing, encoding or carrying data structures used by or associated with such instructions. Non-limiting machine-readable medium examples may include solid-state memories, and optical and magnetic media. Specific examples of machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The instructions 724 may further be transmitted or received over a communications network 726 using a transmission medium via the network interface device 720 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, the network interface device 720 may include one or more physical jacks (e.g., Ethernet, coaxial, or phone jacks) or one or more antennas to connect to the communications network 726. In an example, the network interface device 720 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding or carrying instructions for execution by the machine 700, and includes digital or analog communications signals or other intangible medium to facilitate communication of such software.

It is to be understood that the elements of techniques described herein may be performed by a controller (e.g., controller 104), such as on loading and executing software code or instructions or with other circuitry. The which software code or instructions may be tangibly (e.g., non-transitorily) stored on a tangible computer readable medium, such as on a magnetic medium, e.g., a computer hard drive, an optical medium, e.g., an optical disc, solid-state memory, e.g., flash memory, or other storage media known in the art. Thus, any of the functionality performed by a controller described herein may be implemented in software code or instructions which are tangibly stored on a tangible computer readable medium or hardware circuitry, or a combination. A controller may load software code or instructions via a direct interface with a machine readable medium, via a wired network, via a wireless network, or the like. Upon loading and executing such software code or instructions by the controller, the controller may perform any of the functionality of the controller described herein, including any elements of techniques described herein.

The term “software code” or “code” used herein refers to any instructions or set of instructions that influence the operation of a computer or controller. Instructions may exist in a computer-executable form, such as machine code, which is the set of instructions and data directly executed by a computer's central processing unit or by a controller, a human-understandable form, such as source code, which may be compiled in order to be executed by a computer's central processing unit or by a controller, or an intermediate form, such as object code, which is produced by a compiler. As used herein, the term “software code” or “code” also includes any human-understandable computer instructions or set of instructions, e.g., a script, that may be executed on the fly with the aid of an interpreter executed by a computer's central processing unit or by a controller.

The following, non-limiting examples, detail certain aspects of the present subject matter to solve the challenges and provide the benefits discussed herein, among others.

Example 1 is a system comprising: a transceiver including a buffer to store a voltage difference measured by a differential amplifier from a Controller Area Network (CAN) bus and output the voltage difference; and a controller comprising: an analog to digital converter (ADC) to convert the voltage difference to a digital signal; and processing circuitry to determine a relative margin between a maximum voltage of a detection window and the voltage difference using the digital signal.

In Example 2, the subject matter of Example 1 includes, wherein the detection window is a preselected window having a minimum voltage, a maximum voltage, and a duration.

In Example 3, the subject matter of Examples 1-2 includes, wherein the CAN bus is on an agricultural vehicle.

In Example 4, the subject matter of Examples 1-3 includes, wherein the controller includes a data buffer to store a plurality of voltage differences, including the voltage difference, as a plurality of digital signals.

In Example 5, the subject matter of Example 4 includes, wherein to determine the relative margin, the processing circuitry is further to determine relative margins over time.

In Example 6, the subject matter of Example 5 includes, wherein the processing circuitry is further to output an indication of degradation of relative margins of the plurality of voltage differences over time.

In Example 7, the subject matter of Examples 1-6 includes, wherein the differential amplifier is further to amplify a first voltage from a first line of the CAN bus and a second voltage from a second line of the CAN bus and output the voltage difference based on the amplified first and second voltage.

In Example 8, the subject matter of Examples 1-7 includes, wherein the CAN bus has a line length greater than a maximum standard line length.

In Example 9, the subject matter of Examples 1-8 includes, wherein the CAN bus includes more nodes than a maximum standard number of nodes.

In Example 10, the subject matter of Examples 1-9 includes, wherein the system is a node of the CAN bus.

In Example 11, the subject matter of Examples 1-10 includes, wherein the voltage difference is identified from a signal sent by the transceiver.

In Example 12, the subject matter of Examples 1-11 includes, wherein the voltage difference is identified from a signal sent by another system on the CAN bus.

In Example 13, the subject matter of Examples 1-12 includes, wherein the processing circuitry is to compare the relative margin to a threshold.

In Example 14, the subject matter of Example 13 includes, wherein the processing circuitry is to output an alarm when the relative margin is below the threshold.

In Example 15, the subject matter of Example 14 includes, wherein the threshold is a default threshold.

In Example 16, the subject matter of Examples 14-15 includes, wherein the threshold is a custom threshold that is specified for a particular fleet or vehicle type.

In Example 17, the subject matter of Examples 1-16 includes, wherein the processing circuitry is to output an indication that an addition of a new node caused the relative margin to violate a threshold.

In Example 18, the subject matter of Examples 1-17 includes, wherein the system is a newly installed node on the CAN bus, and wherein the processing circuitry is to output an indication that the newly installed node violates a threshold after installation.

In Example 19, the subject matter of Examples 1-18 includes, wherein the processing circuitry is to compare the relative margin to a diagnostic initial state measurement stored from a factory setting to determine whether the relative margin has degraded.

Example 20 is a controller comprising: an analog to digital converter (ADC) to receive a voltage difference received from a buffer of a transceiver, the voltage difference measured by a differential amplifier from a Controller Area Network (CAN) bus; and processing circuitry to determine a relative margin between the voltage difference and a maximum voltage of a detection window.

In Example 21, the subject matter of Example 20 includes, wherein the detection window is a preselected window having a minimum voltage, a maximum voltage, and a duration.

In Example 22, the subject matter of Examples 20-21 includes, wherein the CAN bus is on an agricultural vehicle.

In Example 23, the subject matter of Examples 20-22 includes, wherein the controller includes a data buffer to store a plurality of voltage differences, including the voltage difference, as a plurality of digital signals.

In Example 24, the subject matter of Example 23 includes, wherein to determine the relative margin, the processing circuitry is further to determine relative margins over time.

In Example 25, the subject matter of Example 24 includes, wherein the processing circuitry is further to output an indication of degradation of relative margins of the plurality of voltage differences over time.

In Example 26, the subject matter of Examples 20-25 includes, wherein the differential amplifier is further to amplify a first voltage from a first line of the CAN bus and a second voltage from a second line of the CAN bus and output the voltage difference based on the amplified first and second voltage.

In Example 27, the subject matter of Examples 20-26 includes, wherein the CAN bus has a line length greater than a maximum standard line length.

In Example 28, the subject matter of Examples 20-27 includes, wherein the CAN bus includes more nodes than a maximum standard number of nodes.

In Example 29, the subject matter of Examples 20-28 includes, wherein the controller is part of a node of the CAN bus.

In Example 30, the subject matter of Examples 20-29 includes, wherein the voltage difference is identified from a signal sent by the transceiver.

In Example 31, the subject matter of Examples 20-30 includes, wherein the voltage difference is identified from a signal sent by another system on the CAN bus.

In Example 32, the subject matter of Examples 20-31 includes, wherein the processing circuitry is to compare the relative margin to a threshold.

In Example 33, the subject matter of Example 32 includes, wherein the processing circuitry is to output an alarm when the relative margin is below the threshold.

In Example 34, the subject matter of Example 33 includes, wherein the threshold is a default threshold.

In Example 35, the subject matter of Examples 33-34 includes, wherein the threshold is a custom threshold that is specified for a particular fleet or vehicle type.

In Example 36, the subject matter of Examples 20-35 includes, wherein the processing circuitry is to output an indication that an addition of a new node caused the relative margin to violate a threshold.

In Example 37, the subject matter of Examples 20-36 includes, wherein the controller is part of a newly installed node on the CAN bus, and wherein the processing circuitry is to output an indication that the newly installed node violates a threshold after installation.

In Example 38, the subject matter of Examples 20-37 includes, wherein the processing circuitry is to compare the relative margin to a diagnostic initial state measurement stored from a factory setting to determine whether the relative margin has degraded.

Example 39 is a method comprising: detecting a voltage difference between two lines of a Controller Area Network (CAN) bus; storing the voltage difference in a buffer; outputting the voltage difference from the buffer to an analog to digital converter (ADC); and determining, using processing circuitry, a relative margin between a digital signal based on the voltage difference output by the ADC and a maximum voltage of a detection window.

In Example 40, the subject matter of Example 39 includes, wherein the detection window is a preselected window having a minimum voltage, a maximum voltage, and a duration.

In Example 41, the subject matter of Examples 39-40 includes, wherein the CAN bus is on an agricultural vehicle.

In Example 42, the subject matter of Examples 39-41 includes, using a data buffer to store a plurality of voltage differences, including the voltage difference, as a plurality of digital signals.

In Example 43, the subject matter of Example 42 includes, wherein determining the relative margin includes determining relative margins over time.

In Example 44, the subject matter of Example 43 includes, outputting an indication of degradation of relative margins of the plurality of voltage differences over time.

In Example 45, the subject matter of Examples 39-44 includes, amplifying, using a differential amplifier, a first voltage from a first line of the CAN bus and a second voltage from a second line of the CAN bus, and outputting the voltage difference based on the amplified first and second voltage.

In Example 46, the subject matter of Examples 39-45 includes, wherein the CAN bus has a line length greater than a maximum standard line length.

In Example 47, the subject matter of Examples 39-46 includes, wherein the CAN bus includes more nodes than a maximum standard number of nodes.

In Example 48, the subject matter of Examples 39-47 includes, wherein the voltage difference is identified from a signal sent by a transceiver.

In Example 49, the subject matter of Examples 39-48 includes, wherein the voltage difference is identified from a signal sent by another system on the CAN bus.

In Example 50, the subject matter of Examples 39-49 includes, comparing the relative margin to a threshold.

In Example 51, the subject matter of Example 50 includes, outputting an alarm when the relative margin is below the threshold.

In Example 52, the subject matter of Example 51 includes, wherein the threshold is a default threshold.

In Example 53, the subject matter of Examples 51-52 includes, wherein the threshold is a custom threshold that is specified for a particular fleet or vehicle type.

In Example 54, the subject matter of Examples 39-53 includes, outputting an indication that an addition of a new node caused the relative margin to violate a threshold.

In Example 55, the subject matter of Examples 39-54 includes, comparing the relative margin to a diagnostic initial state measurement stored from a factory setting to determine whether the relative margin has degraded.

Example 56 is a server comprising: processing circuitry; and memory including instructions, which when executed by the processing circuitry, cause the processing circuitry to: receive a digital signal based on a voltage difference detected at a node of a Controller Area Network (CAN) bus; determine a relative margin between a maximum voltage of a detection window and the voltage difference using the digital signal; compare the relative margin to a threshold; determine that the relative margin is below the threshold; and output an indication that the relative margin is below the threshold.

In Example 57, the subject matter of Example 56 includes, wherein to receive the voltage difference includes to receive a time series of voltage differences, wherein to determine the relative margin includes to determine a plurality of relative margins based on the time series of voltage differences, and wherein the indication includes information indicating a decay of the relative margin over time.

In Example 58, the subject matter of Examples 56-57 includes, wherein the instructions cause the server to send an indication to the node to enter a diagnostic mode, and wherein the voltage difference is detected in the diagnostic mode.

In Example 59, the subject matter of Examples 56-58 includes, wherein the processing circuitry is to receive a data share opt in indication, and wherein the threshold is generated using data from a plurality of CAN busses.

In Example 60, the subject matter of Example 59 includes, wherein the detection window is a preselected window having a minimum voltage, a maximum voltage, and a duration.

In Example 61, the subject matter of Examples 59-60 includes, wherein the CAN bus is on an agricultural vehicle.

In Example 62, the subject matter of Examples 59-61 includes, wherein the node includes a data buffer to store a plurality of voltage differences, including the voltage difference, as a plurality of digital signals.

In Example 63, the subject matter of Example 62 includes, wherein to determine the relative margin, the processing circuitry is further to determine relative margins over time.

In Example 64, the subject matter of Example 63 includes, wherein the processing circuitry is further to output an indication of degradation of relative margins of the plurality of voltage differences over time.

In Example 65, the subject matter of Examples 59-64 includes, wherein the CAN bus has a line length greater than a maximum standard line length.

In Example 66, the subject matter of Examples 59-65 includes, wherein the CAN bus includes more nodes than a maximum standard number of nodes.

In Example 67, the subject matter of Examples 59-66 includes, wherein the voltage difference is identified from a signal sent by a transceiver of the node.

In Example 68, the subject matter of Examples 59-67 includes, wherein the voltage difference is identified from a signal sent by another system on the CAN bus.

In Example 69, the subject matter of Examples 59-68 includes, wherein the processing circuitry is to compare the relative margin to a threshold.

In Example 70, the subject matter of Example 69 includes, wherein the processing circuitry is to output an alarm when the relative margin is below the threshold.

In Example 71, the subject matter of Example 70 includes, wherein the threshold is a default threshold.

In Example 72, the subject matter of Examples 70-71 includes, wherein the threshold is a custom threshold that is specified for a particular fleet or vehicle type.

In Example 73, the subject matter of Examples 59-72 includes, wherein the processing circuitry is to output an indication that an addition of a new node caused the relative margin to violate a threshold.

In Example 74, the subject matter of Examples 59-73 includes, wherein the processing circuitry is to compare the relative margin to a diagnostic initial state measurement stored from a factory setting to determine whether the relative margin has degraded.

Example 75 is a transceiver comprising: an analog to digital converter (ADC) to receive a voltage difference received from a buffer of a transceiver, the voltage difference measured by a differential amplifier from a Controller Area Network (CAN) bus; and processing circuitry to determine a relative margin between the voltage difference and a maximum voltage of a detection window.

Example 76 is a device comprising: an analog to digital converter (ADC) to receive a voltage difference received from a buffer of a transceiver, the voltage difference measured by a differential amplifier from a Controller Area Network (CAN) bus; and processing circuitry to determine a relative margin between the voltage difference and a maximum voltage of a detection window.

Example 77 is a method comprising: capturing a signal corresponding to physical attribute a Controller Area Network (CAN) bus; storing the signal in a buffer; outputting the signal from the buffer to an analog to digital converter (ADC); and determining, using processing circuitry, an attribute of the CAN bus based on a digital output of the ADC.

In Example 78, the subject matter of Example 77 includes, wherein the signal is captured by an oscilloscope.

In Example 79, the subject matter of Examples 77-78 includes, wherein the signal corresponds to at least one of a machine propulsion condition, a machine steering condition, a status condition, an operation condition, a total busload change, or a current environmental condition.

In Example 80, the subject matter of Examples 77-79 includes, wherein determining the attribute includes performing an edge rate analysis.

In Example 81, the subject matter of Examples 77-80 includes, wherein the signal includes an impedance measurement.

In Example 82, the subject matter of Examples 77-81 includes, wherein determining the attribute includes determining a difference pulse width.

In Example 83, the subject matter of Examples 77-82 includes, wherein determining the attribute includes determining a frequency of occurrence of runt pulses or fat pulses on the CAN bus.

Example 84 is at least one machine-readable medium including instructions that, when executed by processing circuitry, cause the processing circuitry to perform operations to implement of any of Examples 1-83.

Example 85 is an apparatus comprising means to implement of any of Examples 1-83.

Example 86 is a system to implement of any of Examples 1-83.

Example 87 is a method to implement of any of Examples 1-83.

Method examples described herein may be machine or computer-implemented at least in part. Some examples may include a computer-readable medium or machine-readable medium encoded with instructions operable to configure an electronic device to perform methods as described in the above examples. An implementation of such methods may include code, such as microcode, assembly language code, a higher-level language code, or the like. Such code may include computer readable instructions for performing various methods. The code may form portions of computer program products. Further, in an example, the code may be tangibly stored on one or more volatile, non-transitory, or non-volatile tangible computer-readable media, such as during execution or at other times. Examples of these tangible computer-readable media may include, but are not limited to, hard disks, removable magnetic disks, removable optical disks (e.g., compact disks and digital video disks), magnetic cassettes, memory cards or sticks, random access memories (RAMs), read only memories (ROMs), and the like.

What is claimed is:

1. A system comprising:
a transceiver including a buffer to store a voltage difference measured by a differential amplifier from a Controller Area Network (CAN) bus and output the voltage difference; and
a controller comprising:
an analog to digital converter (ADC) to convert the voltage difference to a digital signal; and
processing circuitry to determine a relative margin between a maximum voltage of a detection window and the voltage difference using the digital signal.

2. The system of claim 1, wherein the detection window is a preselected window having a minimum voltage, a maximum voltage, and a duration.

3. The system of claim 1, wherein the CAN bus is on an agricultural vehicle.

4. The system of claim 1, wherein the controller includes a data buffer to store a plurality of voltage differences, including the voltage difference, as a plurality of digital signals.

5. The system of claim 4, wherein to determine the relative margin, the processing circuitry is further to determine relative margins over time.

6. The system of claim 5, wherein the processing circuitry is further to output an indication of degradation of relative margins of the plurality of voltage differences over time.

7. The system of claim 1, wherein the differential amplifier is further to amplify a first voltage from a first line of the CAN bus and a second voltage from a second line of the CAN bus and output the voltage difference based on the amplified first and second voltage.

8. The system of claim 1, wherein the CAN bus has a line length greater than a maximum standard line length or the CAN bus includes more nodes than a maximum standard number of nodes.

9. The system of claim 1, wherein the voltage difference is identified from a signal sent by another system on the CAN bus.

10. The system of claim 1, wherein the processing circuitry is to:
compare the relative margin to a threshold, and
output an alarm when the relative margin is below the threshold.

11. The system of claim 10, wherein the threshold is a custom threshold that is specified for a particular fleet or vehicle type.

12. The system of claim 1, wherein the processing circuitry is to output an indication that an addition of a new node caused the relative margin to violate a threshold.

13. The system of claim 1, wherein the system is a newly installed node on the CAN bus, and wherein the processing circuitry is to output an indication that the newly installed node violates a threshold after installation.

14. The system of claim 1, wherein the processing circuitry is to compare the relative margin to a diagnostic initial state measurement stored from a factory setting to determine whether the relative margin has degraded.

15. A controller comprising:
an analog to digital converter (ADC) to receive a voltage difference received from a buffer of a transceiver, the voltage difference measured by a differential amplifier from a Controller Area Network (CAN) bus; and
processing circuitry to determine a relative margin between the voltage difference and a maximum voltage of a detection window.

16. The controller of claim 15, wherein the detection window is a preselected window having a minimum voltage, a maximum voltage, and a duration.

17. The controller of claim 15, wherein the CAN bus is on an agricultural vehicle.

18. The controller of claim 15, wherein the controller includes a data buffer to store a plurality of voltage differences, including the voltage difference, as a plurality of digital signals.

19. The controller of claim 15, wherein to determine the relative margin, the processing circuitry is further to determine relative margins over time.

20. A method comprising:
detecting a voltage difference between two lines of a Controller Area Network (CAN) bus;
storing the voltage difference in a buffer;
outputting the voltage difference from the buffer to an analog to digital converter (ADC); and
determining, using processing circuitry, a relative margin between a digital signal based on the voltage difference output by the ADC and a maximum voltage of a detection window.
